(19) United States
(12) Patent Application Publication
(10) Pub. No.: US 2008/0191264 A1
(43) Pub. Date: Aug. 14, 2008

(54) Non-volatile memory devices and methods of operating and fabricating the same

(75) Inventors: Won-Joo Kim, Hwaseong-si (KR); Yoon-dong Park, Yongin-si (KR); June-mo Koo, Seoul (KR); Suk-pil Kim, Yongin-si (KR); Tae-hee Lee, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/010,139

(22) Filed: Jan. 22, 2008

(30) Foreign Application Priority Data
Jan. 24, 2007 (KR) 10-2007-0007642

(51) Int. Cl. H01L 29/00; H01L 21/3205

(52) U.S. Cl. 257/319; 438/587; 257/E29.001; 257/E21.294

(57) ABSTRACT

Non-volatile memory devices highly integrated using an oxide based compound semiconductor and methods of operating and fabricating the same are provided. A non-volatile memory device may include one or more oxide based compound semiconductor layers. A plurality of auxiliary gate electrodes may be arranged to be insulated from the one or more oxide based compound semiconductor layers. A plurality of control gate electrodes may be positioned between adjacent pairs of the plurality of auxiliary gate electrodes at a different level from the plurality of auxiliary gate electrodes. The plurality of control gate electrodes may be insulated from the one or more oxide based compound semiconductor layers. A plurality of charge storing layers may be interposed between the one or more oxide based compound semiconductor layers and the plurality of control gate electrodes.

### PRIORITY STATEMENT

This application claims priority under 35 U.S.C. §119 to Korean Patent Application No. 2007-0007642, filed on Jan. 24, 2007, in the Korean Intellectual Property Office (KIPO), the entire contents of which are herein incorporated by reference.

### BACKGROUND

1. Field

Example embodiments relate to non-volatile memory devices and methods of operating and fabricating the same.

2. Description of Related Art

Non-volatile memory devices having typical silicon substrates have begun to reach limitations in regards to degree of integration and operating speed. Therefore, research on various compound semiconductor materials for use as a substitute for silicon has been recently conducted. For example, an oxide based compound semiconductor material has been used for light emitting devices (LEDs). In particular, a light emitting device using a ZnO compound semiconductor and a method of fabricating the light emitting device have been developed. In this case, ZnO may be stacked on the silicon substrate.

However, it is difficult to form a junction in an oxide based compound semiconductor unlike in silicon. As such, it is more difficult to define source and drain regions on oxide based compound semiconductors. It is also more difficult to fabricate non-volatile memory devices having a NAND structure using oxide based compound semiconductors and to improve the degree of integration of the non-volatile memory devices.

### SUMMARY

Example embodiments provide non-volatile memory devices more highly integrated using an oxide based compound semiconductor. Example embodiments also provide a more efficient method of operating the non-volatile memory devices and a method of fabricating the non-volatile memory devices.

According to example embodiments, a non-volatile memory device may comprise one or more oxide based compound semiconductor layers, a plurality of auxiliary gate electrodes insulated from the one or more oxide based compound semiconductor layers, a plurality of control gate electrodes positioned between adjacent pairs of the plurality of auxiliary gate electrodes at a different level from the plurality of auxiliary gate electrodes and insulated from the one or more oxide based compound semiconductor layers, and a plurality of charge storing layers between the one or more oxide based compound semiconductor layers and the plurality of control gate electrodes.

The one or more oxide based compound semiconductor layers may include a plurality of oxide based compound semiconductor layers separately positioned in strings. The non-volatile memory device may further comprise an isolation layer interposed between the plurality of oxide based compound semiconductor layers. The non-volatile memory device may further comprise a substrate electrode under the bottom surfaces of the plurality of oxide based compound semiconductor layers.

The plurality of control gate electrodes may be formed on the top surfaces of the one or more oxide based compound semiconductor layers, and the plurality of auxiliary gate electrodes may be formed to be recessed into the one or more oxide based compound semiconductor layers.

The plurality of control gate electrodes may be formed to be recessed into the one or more oxide based compound semiconductor layers, and the plurality of auxiliary gate electrodes may be formed on the top surfaces of the one or more oxide based compound semiconductor layers.

According to example embodiments, a method of operating the non-volatile memory device may comprise a program operation for storing data in a first charge storing layer selected from among the plurality of charge storing layers, and a read operation for reading a data state of a second charge storing layer selected from among the plurality of charge storing layers. A first pass voltage may be applied to the plurality of auxiliary gate electrodes in the program and read operations.

The method may further comprise an erase operation simultaneously erasing data stored in the plurality of charge storing layers.

According to example embodiments, a method of fabricating a non-volatile memory device may comprise providing one or more oxide based compound semiconductor layers, forming a plurality of auxiliary gate electrodes to be insulated from the one or more oxide based compound semiconductor layers, forming a plurality of control gate electrodes to be positioned between adjacent pairs of the plurality of auxiliary gate electrodes at a different level from the plurality of auxiliary gate electrodes and insulated from the one or more oxide based compound semiconductor layers, and forming a plurality of charge storing layers between the one or more oxide based compound semiconductor layers and the plurality of control gate electrodes.

### BRIEF DESCRIPTION OF THE DRAWINGS

Example embodiments will be more clearly understood from the following detailed description taken in conjunction with the accompanying drawings. FIGS. 1-12 represent non-limiting, example embodiments as described herein.

FIG. 1 is a perspective view of a non-volatile memory device according to an example embodiment;

FIG. 2 is a perspective view of a non-volatile memory device according to an example embodiment;

FIG. 3 is a perspective view of a non-volatile memory device according to an experiment corresponding to a portion of the non-volatile memory device of FIG. 1;

FIG. 4 is a plan view illustrating a simulation of the electron density distribution of the non-volatile memory device of FIG. 3;

FIG. 5 is a graph illustrating voltage-current characteristics of the non-volatile memory device of FIG. 3;

FIG. 6 is a perspective view of a non-volatile memory device according to an experiment corresponding to a portion of the non-volatile memory device of FIG. 2;

FIG. 7 is a plan view illustrating a simulation of the electron density distribution of the non-volatile memory device of FIG. 6;

FIG. 8 is a graph illustrating voltage-current characteristics of the non-volatile memory device of FIG. 6; and

FIGS. 9 through 12 are perspective views illustrating a method of fabricating a non-volatile memory device according to example embodiments.

### DETAILED DESCRIPTION OF EXAMPLE EMBODIMENTS

Reference will now be made in detail to example embodiments, examples of which are illustrated in the accompanying drawings. However, example embodiments are not limited to the embodiments illustrated hereinafter, and the embodiments herein are rather introduced to provide easy and complete understanding of the scope and spirit of example embodiments. In the drawings, the thicknesses of layers and regions are exaggerated for clarity.

It will be understood that when an element or layer is referred to as being “on,” “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Non-volatile memory devices according to example embodiments may include an EEPROM and/or a flash memory device, but is not limited thereto.

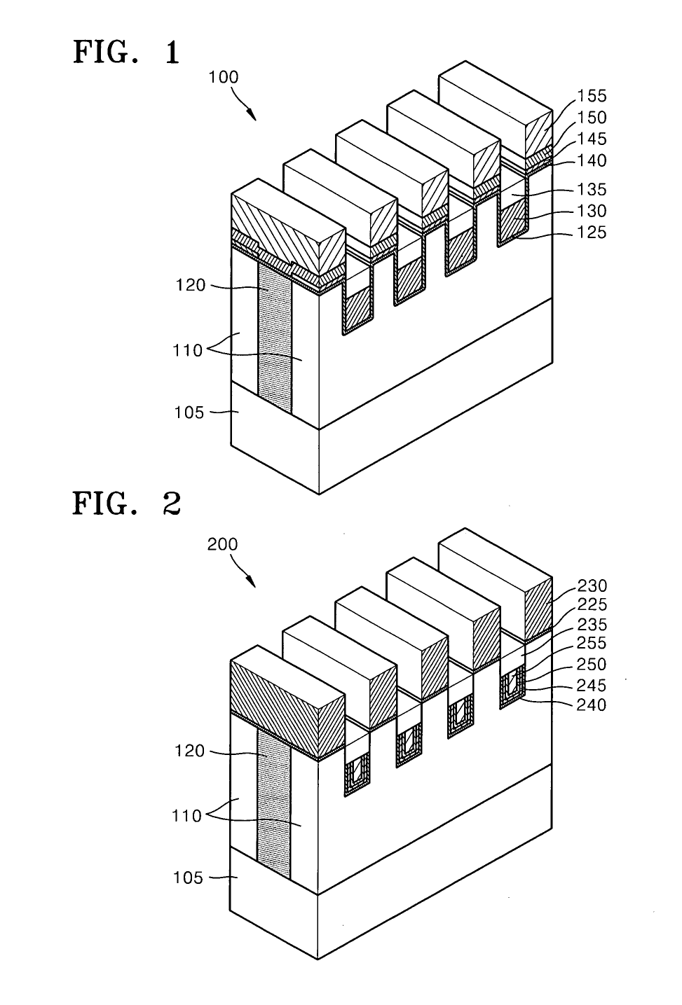

FIG. 1 is a perspective view of a non-volatile memory device 100 according to an example embodiment.

Referring to FIG. 1, a pair of oxide based compound semiconductor layers 110 are provided. Each of the oxide based compound semiconductor layers 110 may include a group II-VI oxide (e.g., ZnO). Each of the oxide based compound semiconductor layers 110 may be arranged in strings and used in a non-volatile memory device having a NAND structure. The number of oxide based compound semiconductor layers 110 is illustrative, and thus, the number of oxide based compound semiconductor layers 110 may be selected to be one or a plurality depending on the capacity of the non-volatile memory device 100.

Alternatively, an isolation layer 120 may be interposed between the oxide based compound semiconductor layers 110. The isolation layer 120 may be used to isolate and insulate the oxide based compound semiconductor layers 110 from each other. The isolation layer 120 may include an oxide or an insulating layer.

A plurality of auxiliary gate electrodes 130 may be formed to be recessed into the oxide based compound semiconductor layers 110. A plurality of gate insulating layers 125 may be interposed between the auxiliary gate electrodes 130 and the oxide based compound semiconductor layers 110. The top surface of each of the auxiliary gate electrodes 130 may be lower than the top surface of each of the oxide based compound semiconductor layers 110. A plurality of capping insulating layers 135 may be formed on each of the auxiliary gate electrodes 130.

Each of the auxiliary gate electrodes 130 may include a conductive layer (e.g., a poly-silicon, a metal, or a metal silicide layer). Each of the gate insulating layers 125 may include an oxide layer, a nitride layer, or a high dielectric constant layer. The high dielectric constant layer may refer to an insulating layer having a dielectric constant larger than the oxide and nitride layers.

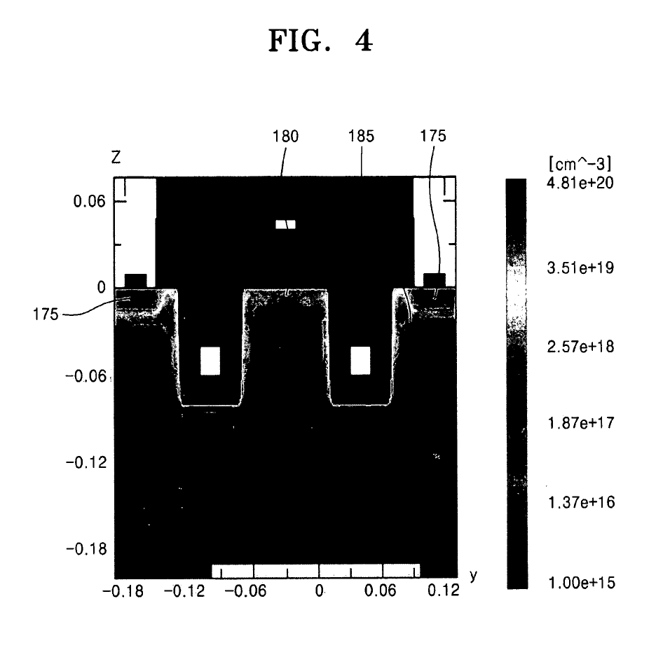

The auxiliary gate electrodes 130 and the oxide based compound semiconductor layers 110 may constitute auxiliary transistors. A channel region (e.g., a first channel region 185 of FIG. 4) of each of the auxiliary transistors may be formed near surfaces of the oxide based compound semiconductor layers 110 surrounding the auxiliary gate electrodes 130. Each of the auxiliary transistors having such a structure may be referred to as a recess or a trench type. As will be described later, such auxiliary transistors may function to connect memory transistors (not shown) to one another.

A plurality of control gate electrodes 155 may be positioned between adjacent pairs of the auxiliary gate electrodes 130. The control gate electrodes 155 may be positioned on the top surfaces of the oxide based compound semiconductor layers 110 to be higher than the top surfaces of the auxiliary gate electrodes 130. In the non-volatile memory device 100 having a NAND structure, each of the control gate electrodes 155 may extend across the oxide based compound semiconductor layers 110.

A plurality of charge storing layers 145 may be interposed between each of the control gate electrodes 155 and the oxide based compound semiconductor layers 110. Each of the charge storing layers 145 may be defined on one of the oxide based compound semiconductor layers 110, or may extend across the oxide based semiconductor layers 110. Alternatively, a plurality of tunneling insulating layers 140 may be interposed between the oxide based compound semiconductor layers 110 and each of the charge storing layers 145. A plurality of blocking insulating layers 150 may be interposed between each of the charge storing layers 145 and the control gate electrodes 155.

Each of the control gate electrodes 155 may include a conductive layer (e.g., a poly-silicon, a metal or a metal silicide layer). Each of the charge storing layers 145 may include poly-silicon, a silicon nitride layer, nanocrystals, or dots. The dots and nanocrystals may include fine crystals of a metal or a semiconductor material. Each of the tunneling insulating layers 140 and the blocking insulating layers 150 may include an oxide layer, a nitride layer, or a high dielectric constant layer.

The stacked structure of the oxide based compound semiconductor layers 110, the charge storing layers 145, and the control gate electrodes 155 may constitute memory transistors. A channel region (e.g., a second channel region 180 of FIG. 4) of each of the memory transistors may be formed near the surfaces of the oxide based compound semiconductor layers 110 below the control gate electrodes 155. The non-volatile memory device 100 may have a NAND structure, and the memory transistors may be arrayed in series.

Alternatively, a substrate electrode 105 may be positioned under the bottom surfaces of the oxide based compound semiconductor layers 110. The substrate electrode 105 may form an ohmic contact with the oxide based compound semiconductor layers 110. The substrate electrode 105 may be used to apply a bias voltage to the oxide based compound semiconductor layers 110.

In the non-volatile memory device 100, although the control and auxiliary gate electrodes 155 and 130 are arranged at different levels, the control and auxiliary gate electrodes 155 and 130 may be arranged to be close to each other in a predetermined or given plane. Accordingly, the degree of integration of the non-volatile memory device 100 may be increased. Moreover, because the oxide based compound semiconductor layers 110 may be formed as double layers, the non-volatile memory device 100 may also have a higher degree of integration.

Hereinafter, a method of operating the non-volatile memory device 100 will be described. In a program operation, data may be stored in a first charge storing layer 145 selected from among the charge storing layers 145. In a read operation, the data state of a second charge storing layer 145 selected from among the charge storing layers 145 may be read. In an erase operation, data stored in the charge storing layers 145 may be simultaneously erased.

A first pass voltage may be applied to the auxiliary gate electrodes 130 in a program operation. A program voltage may be applied to one control gate electrode 155 on the first charge storing layer 145, and a second pass voltage may be applied to the other control gate electrodes 155. In a read operation, the first pass voltage may be applied to the auxiliary gate electrodes 130. A read voltage may be applied to one control gate electrode 155 on the second charge storing layer 145, and the second pass voltage may be applied to the other control gate electrodes 155.

The first and second pass voltages may be selected to allow the auxiliary and memory transistors to be turned on, respectively. A higher voltage may be selected as the program voltage so that tunneling of electric charges between the oxide based compound semiconductor layers 110 and the first charge storing layer 145 may be permitted. The read voltage may be appropriately selected depending on the state of the second charge storing layer 145.

In an erase operation, the control gate electrodes 155 may be grounded, and an erase voltage may be applied to the substrate electrode 105. The auxiliary gate electrodes 130 may be floated. A higher voltage may be selected as the erase voltage so that tunneling of electric charges between the oxide based compound semiconductor layers 110 and the first charge storing layer 145 may be permitted.

FIG. 2 is a perspective view of a non-volatile memory device 200 according to an example embodiment. The non-volatile memory device 200 corresponds to the non-volatile memory device of FIG. 1 having the positions of the memory and auxiliary transistors swapped with each other. Thus, descriptions overlapping with the aforementioned example embodiment will be omitted.

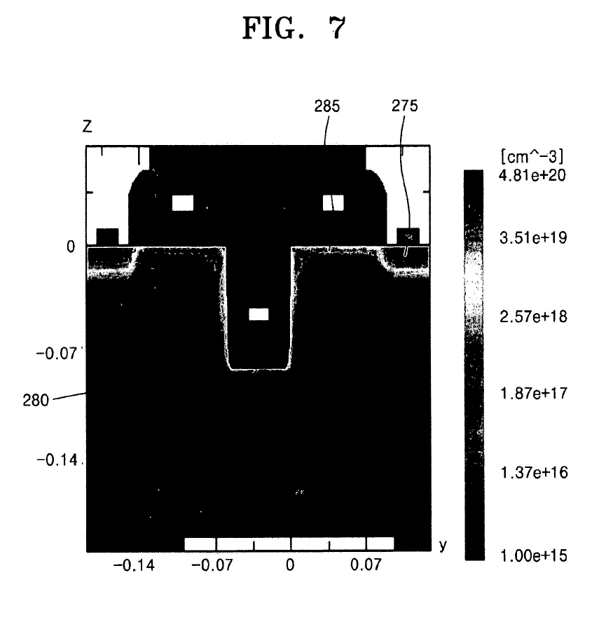

Referring to FIG. 2, a plurality of auxiliary gate electrodes 230 may be formed on the top surfaces of oxide based compound semiconductor layers 110. A plurality of gate insulating layers 225 may be interposed between each of the auxiliary gate electrodes 230 and the oxide based compound semiconductor layers 110. The auxiliary gate electrodes 230 and the oxide based compound semiconductor layers 110 may constitute auxiliary transistors. A channel region (e.g., a first channel region 285 of FIG. 7) of each of the auxiliary transistors may be formed near the surfaces of the oxide based compound semiconductor layers 110 below the auxiliary gate electrodes 230.

A plurality of control gate electrodes 255 may be positioned between adjacent pairs of the auxiliary gate electrodes 230. The control gate electrodes 255 may be formed to be recessed into the oxide based compound semiconductor layers 110. Thus, the control gate electrodes 255 may be positioned lower than the auxiliary gate electrodes 230. A plurality of capping insulating layers 235 may be formed on each of the control gate electrodes 255.

A plurality of charge storing layers 245 may be interposed between each of the control gate electrodes 255 and the oxide based compound semiconductor layers 110. Alternatively, a plurality of tunneling insulating layers 240 may be interposed between the oxide based compound semiconductor layers 110 and each of the charge storing layers 245. A plurality of blocking insulating layers 250 may be interposed between each of the charge storing layers 245 and the control gate electrodes 255.

The stacked structure of the oxide based compound semiconductor layers 110, the charge storing layers 245, and the control gate electrodes 255 may constitute memory transistors. A channel region (e.g., a second channel region 280 of FIG. 7) of each of the memory transistors may be formed near the surfaces of the oxide based compound semiconductor layers 110 surrounding the control gate electrodes 255.

It may be well known to those skilled in the art that a method of operating the non-volatile memory device 200 may be implemented in reference to the method of operating the non-volatile memory device 100 of FIG. 1.

Further, in example embodiments, a non-volatile memory device may include a plurality of blocks (not shown). In this case, the non-volatile memory device 100 of FIG. 1 or the non-volatile memory device 200 of FIG. 2 may form a plurality of blocks. Thus, the oxide based compound semiconductor layers 110 and the substrate electrodes 105 may be divided into the aforementioned blocks. The substrate electrodes 105 of the blocks may be individually controlled.

Accordingly, operations of the non-volatile memory device may be divided. For example, an erase operation may be performed in a first block, and a read or a program operation may be performed in a second block. The first and second blocks may be simultaneously operated. This may occur because the substrate electrodes 105 of the first and second blocks may be isolated from each other.

Therefore, blocks may be simultaneously operated using the non-volatile memory device according to example embodiments, thereby enhancing the operating speed and efficiency of the non-volatile memory device.

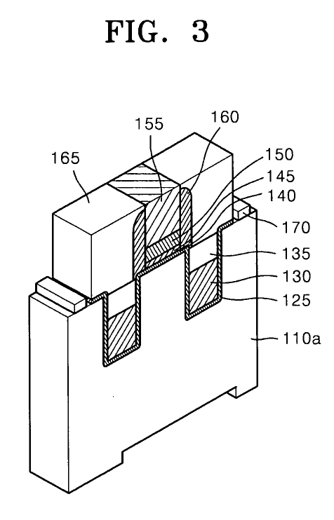

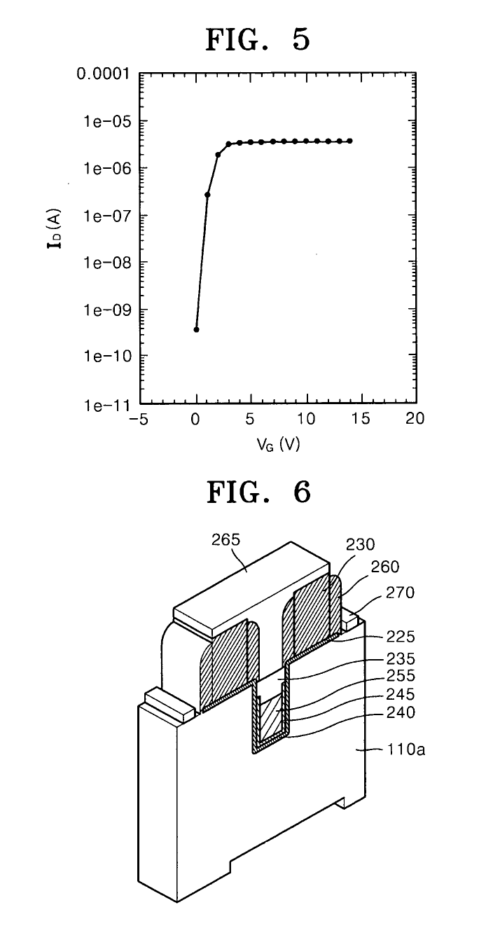

FIG. 3 is a perspective view of a non-volatile memory device according to an experiment corresponding to a portion of the non-volatile memory device 100 of FIG. 1. FIG. 4 is a plan view illustrating a simulation of the electron density distribution of the non-volatile memory device of FIG. 3. FIG. 5 is a graph illustrating voltage-current characteristics of the non-volatile memory device of FIG. 3.

Referring to FIG. 3, a typical silicon substrate 110a may be used instead of the oxide based compound semiconductor layers 110 of FIG. 1, and the substrate electrode 105 of FIG. 1 may be omitted for convenience of the simulation. Spacer insulating layers 160 may be formed on both sidewalls of a control gate electrode 155, and interlayer dielectric layers 165 may be formed on the silicon substrate 110a. Auxiliary gate electrodes 130 and the control gate electrode 155 may be formed of Ti, and a charge storing layer 145 may be formed as a silicon nitride layer. A contact plug 170 may be formed of W on the silicon substrate 110a along the surface of each of the interlayer dielectric layers 165 (e.g., at a point outside of each of the auxiliary gate electrodes 130).

Referring to FIGS. 3 and 4, a first pass voltage may be applied to the auxiliary gate electrodes 130, and a second pass voltage may be applied to the control gate electrode 155. A source or drain region 175 may be defined in the silicon substrate 110a to be connected to the contact plug 170, and a desired, or alternatively, a predetermined operating voltage may be applied to the contact plug 170.

The electron density distribution illustrated in FIG. 4 will now be discussed. A first channel region 185 may be formed near the surfaces of the silicon substrate 110a surrounding the auxiliary gate electrodes 130, and a second channel region 180 may be formed near the surface of the silicon substrate 110a below the control gate electrode 155. Moreover, the first and second channel regions 185 and 180 may be connected to each other. That is, the first channel region 185 may perform a function similar to the source or drain region of each memory transistor. Accordingly, although the source and/or drain regions may be omitted between the memory transistors, the memory transistors may be connected in series.

As illustrated in FIG. 5, the change in current I_{D} between the source and drain regions 175 may depend on the voltage V_{G} applied to the control gate electrode 155. The illustrated voltage V_{G}-current I_{D} characteristics may be similar to that of a typical transistor.

It may be well known to those skilled in the art that the results illustrated in FIGS. 3 through 5 may be identically applied to a non-volatile memory device including the oxide based compound semiconductor layers 110 (FIG. 1) instead of the silicon substrate 110a by varying the operating conditions. Thus, the normal operation of the non-volatile memory device 100 of FIG. 1 may be indirectly inferred.

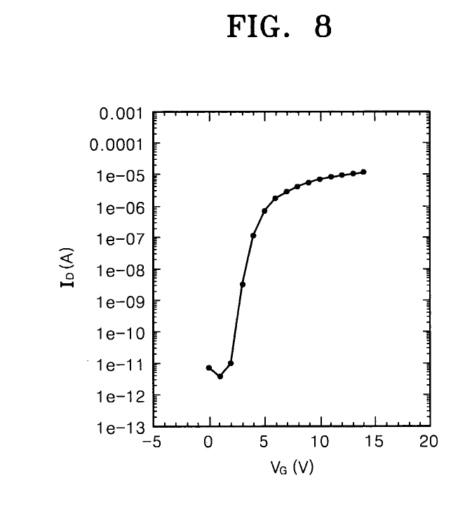

FIG. 6 is a perspective view of a non-volatile memory device according to an experiment corresponding to a portion of the non-volatile memory device 200 of FIG. 2. FIG. 7 is a plan view illustrating a simulation of the electron density distribution of the non-volatile memory device of FIG. 6. FIG. 8 is a graph illustrating voltage-current characteristics of the non-volatile memory device of FIG. 6.

Referring to FIG. 6, a typical silicon substrate 110a may be used instead of the oxide based compound semiconductor layers 110 of FIG. 2, and the substrate electrode 105 of FIG. 2 may be omitted for convenience of the simulation. In the memory transistors, the blocking insulating layers 150 of FIG. 2 may be omitted. Spacer insulating layers 260 may be formed on both sidewalls of each of auxiliary gate electrodes 230, and an interlayer dielectric layer 265 may be formed on the silicon substrate 110a. The auxiliary gate electrodes 230 and a control gate electrode 255 may be formed of Ti, and a charge storing layer 245 may be formed as a silicon nitride layer. A contact plug 270 may be formed of W on the silicon substrate 110a at a point outside of each of the auxiliary gate electrodes 230.

Referring to FIGS. 6 and 7, a first pass voltage may be applied to the auxiliary gate electrodes 230, and a second pass voltage may be applied to the control gate electrode 255. A source or drain region 275 may be defined on the silicon substrate 110a so as to be connected to the contact plug 270, and a desired, or alternatively, a predetermined operating voltage may be applied to the contact plug 270.

The electron density distribution illustrated in FIG. 7 will now be discussed. A first channel region 285 may be formed near the surface of the silicon substrate 110a below the auxiliary gate electrodes 230, and a second channel region 280 may be formed near the surface of the silicon substrate 110a surrounding the control gate electrode 255. Moreover, the first and second channel regions 285 and 280 may be connected to each other.

As illustrated in FIG. 8, the change in current I_{D} between the source and drain regions 275 may depend on the voltage V_{G} applied to the control gate electrode 255. The illustrated voltage V_{G}-current I_{D} characteristics may be similar to that of a typical transistor.

It may be well known to those skilled in the art that the results illustrated in FIGS. 6 through 8 may be identically applied to a non-volatile memory device including the oxide based compound semiconductor layers 110 (FIG. 2) instead of the silicon substrate 110a by varying the operating conditions. Thus, normal operation of the non-volatile memory device 100 of FIG. 2 may be indirectly inferred.

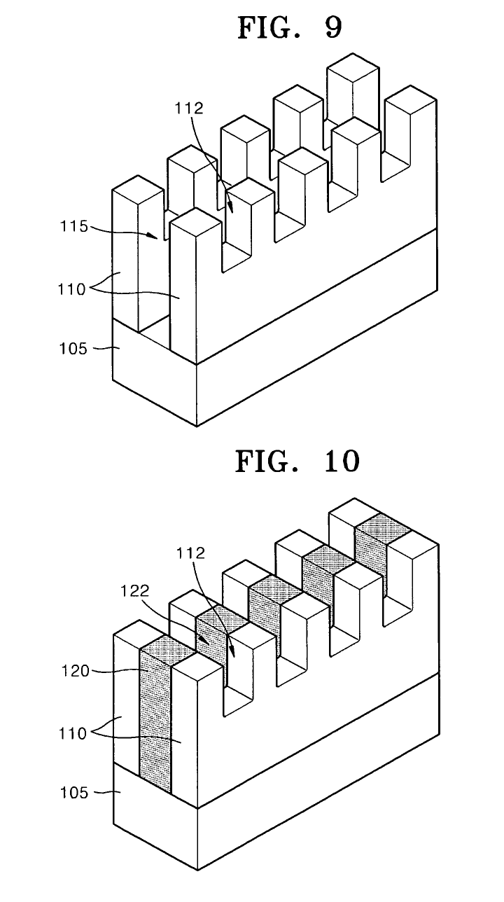

FIGS. 9 through 12 are perspective views illustrating a method of fabricating a non-volatile memory device according to example embodiments.

Referring to FIG. 9, one or more oxide based compound semiconductor layers 110 may be formed on a substrate electrode 105. Each of the oxide based compound semiconductor layers 110 may include a plurality of first trenches 112. The oxide based compound semiconductor layers 110 may be spaced apart from each other to have a second trench 115 interposed therebetween. The depth of each of the first trenches 112 may be smaller than that of the second trench 115. Alternatively, the edge portions of each of the first and second trenches 112 and 115 may have the shape of a smooth curve.

Referring to FIG. 10, an isolation layer 120 may be formed between the oxide based compound semiconductor layers 110. The isolation layer 120 may include third trenches 122 at positions corresponding to the first trenches 112. For example, the third trench 122 may be formed by filling an insulating layer in the second trench 115, and then etching the insulating layer such that the isolation layer 120 is formed.

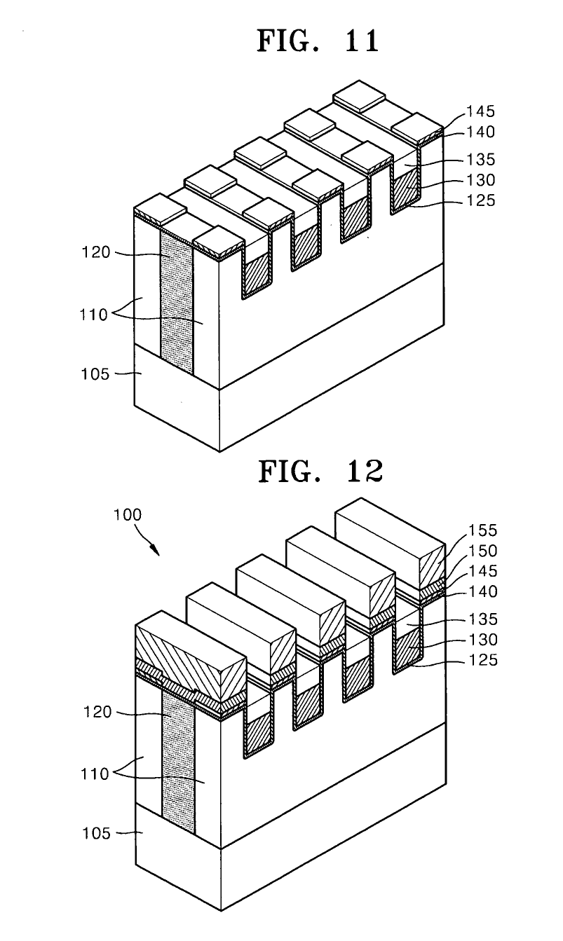

Referring to FIG. 11, gate insulating layers 125 may be formed on the surfaces of the first trenches 112. Auxiliary gate electrodes 130 may then be formed in the first trenches 112 to at least partially fill the first trenches 112. That is, the auxiliary gate electrodes 130 may be formed to be recessed into the oxide based compound semiconductor layers 110. For example, a conductive layer may be formed to fill in the first trenches 112. The conductive layer may then be partially etched or planarized, thereby forming the auxiliary gate electrodes 130.

Alternatively, capping insulating layers 135 may be formed on the auxiliary gate electrodes in the first trenches.

Tunneling insulating layers 140 may be formed on the top surfaces of the oxide based compound semiconductor layers 110. The gate insulating layers 125 and the tunneling insulating layers 140 may be formed simultaneously to be connected to one another. Charge storing layers 145 may then be formed on the tunneling insulating layers 140. Each of the charge storing layers 145 may be defined on the oxide based compound semiconductor layers 110 between adjacent pairs of the auxiliary gate electrodes 130. Alternatively, each of the charge storing layers 145 may extend across the oxide based compound semiconductor layers 110.

Referring to FIG. 12, blocking insulating layers 150 may be formed on the charge storing layers 145. Control gate electrodes 155 may be formed on the blocking insulating layers 150. Each of the control gate electrodes 155 may be defined on the oxide based compound semiconductor layers 110 between adjacent pairs of the auxiliary gate electrodes 130. Alternatively, each of the control gate electrodes 155 may extend across the oxide based compound semiconductor layers 110.

A non-volatile memory device (100 of FIG. 1) may then be completed in accordance with a process known to those skilled in the art.

It may be well known to those skilled in the art that the aforementioned method of fabricating the non-volatile memory device 100 of FIG. 1 may be modified and then applied to the non-volatile memory device 200 of FIG. 2. In this case, the tunneling insulating layers 240, the charge storing layers 245, the blocking insulating layers 250 and the control gate electrodes 255 may be formed in the first trenches 112 illustrated in FIG. 10. Thereafter, the gate insulating layers 225 and the auxiliary gate electrodes 230 may be formed on the top surfaces of the oxide based compound semiconductor layers 110.

In non-volatile memory devices according to example embodiments, control and auxiliary gate electrodes may be arranged to be close to each other in a predetermined or given plane. Accordingly, the degree of integration of the non-volatile memory devices may be increased. Moreover, oxide based compound semiconductor layers may be stacked such that the non-volatile memory devices are formed into a multi-layered structure, thereby increasing the degree of integration of the non-volatile memory devices.

In the non-volatile memory devices according to example embodiments, oxide based compound semiconductor layers may be divided into a plurality of blocks, in which the blocks may be simultaneously operated. Accordingly, the operating speed and efficiency of the non-volatile memory devices may be improved.

The foregoing is illustrative of example embodiments and is not to be construed as limiting thereof. Although example embodiments have been described, those skilled in the art will readily appreciate that many modifications are possible in example embodiments without materially departing from the novel teachings and advantages of example embodiments. Accordingly, all such modifications are intended to be included within the scope of the claims. Therefore, it is to be understood that the foregoing is illustrative of example embodiments and is not to be construed as limited to the specific embodiments disclosed, and that modifications to the disclosed embodiments, as well as other embodiments, are intended to be included within the scope of the appended claims. Example embodiments are defined by the following claims, with equivalents of the claims to be included therein.

1. A non-volatile memory device, comprising:
one or more oxide based compound semiconductor layers;
a plurality of auxiliary gate electrodes insulated from the one or more oxide based compound semiconductor layers;
a plurality of control gate electrodes respectively positioned between adjacent pairs of the plurality of auxiliary gate electrodes at a different level from the plurality of auxiliary gate electrodes, the plurality of control gate electrodes being insulated from the one or more oxide based compound semiconductor layers; and
a plurality of charge storing layers respectively between the one or more oxide based compound semiconductor layers and the plurality of control gate electrodes.

2. The non-volatile memory device of claim 1, wherein the one or more oxide based compound semiconductor layers includes a plurality of oxide based compound semiconductor layers separately positioned in strings.

3. The non-volatile memory device of claim 1, further comprising:
an isolation layer between the plurality of oxide based compound semiconductor layers.

4. The non-volatile memory device of claim 1, further comprising:
a substrate electrode under the bottom surfaces of the plurality of oxide based compound semiconductor layers.

5. The non-volatile memory device of claim 1, wherein the plurality of oxide based compound semiconductor layers are divided into a plurality of blocks, and a plurality of substrate electrodes are further formed to be in contact with the blocks of the plurality of oxide based compound semiconductor layers, respectively.

6. The non-volatile memory device of claim 1, wherein the plurality of control gate electrodes are formed on top surfaces of the one or more oxide based compound semiconductor layers, and the plurality of auxiliary gate electrodes are formed to be recessed into the one or more oxide based compound semiconductor layers.

7. The non-volatile memory device of claim 6, further comprising:
a first channel region near surfaces of the one or more oxide based compound semiconductor layers surrounding the plurality of auxiliary gate electrodes; and
a second channel region near surfaces of the one or more oxide based compound semiconductor layers below the plurality of control gate electrodes,
wherein the first and second channel regions are connected to each other.

8. The non-volatile memory device of claim 6, further comprising:
a plurality of capping insulating layers respectively on the plurality of auxiliary gate electrodes.

9. The non-volatile memory device of claim 1, wherein the plurality of control gate electrodes are formed to be recessed into the one or more oxide based compound semiconductor layers, and the plurality of auxiliary gate electrodes are formed on the top surfaces of the one or more oxide based compound semiconductor layers.

10. The non-volatile memory device of claim 9, further comprising:
a plurality of capping insulating layers respectively on the plurality of control gate electrodes.

11. The non-volatile memory device of claim 9, further comprising:
a first channel region near surfaces of the one or more oxide based compound semiconductor layers below the plurality of auxiliary gate electrodes; and
a second channel region near surfaces of the one or more oxide based compound semiconductor layers surrounding the plurality of control gate electrodes,
wherein the first and second channel regions are connected to each other.

12. The non-volatile memory device of claim 1, further comprising:
a plurality of tunneling insulating layers respectively between the one or more oxide based compound semiconductor layers and the plurality of charge storing layers; and
a plurality of blocking insulating layers respectively between the plurality of charge storing layers and the plurality of control gate electrodes.

13. The non-volatile memory device of claim 1, further comprising:
a plurality of gate insulating layers respectively between the one or more oxide based compound semiconductor layers and the plurality of auxiliary gate electrodes.

14. The non-volatile memory device of claim 1, wherein the oxide based compound semiconductor layer comprises ZnO.

15. A method of operating the non-volatile memory device of claim 1, comprising:
a program operation for storing data in a first charge storing layer selected from among the plurality of charge storing layers; and
a read operation for reading a data state of a second charge storing layer selected from among the plurality of charge storing layers,
wherein a first pass voltage is applied to the plurality of auxiliary gate electrodes in the program and read operations.

16. The method of claim 15, wherein, in the program operation, a program voltage is applied to a first control gate electrode positioned on the selected first charge storing layer, the first control gate electrode being from among the plurality of control gate electrodes, and further wherein, a second pass voltage is applied to the other control gate electrodes.

17. The method of claim 15, wherein in the read operation, a read voltage is applied to a second control gate electrode positioned on the selected second charge storing layer, the second control gate electrode being from among the plurality of control gate electrodes, and further wherein, a second pass voltage is applied to the other control gate electrodes.

18. The method of claim 15, further comprising:
an erase operation simultaneously erasing data stored in the plurality of charge storing layers.

19. The method of claim 15, further comprising:
an erase operation dividing the plurality of charge storing layers into a plurality of blocks and simultaneously erasing data of a first block selected from among the plurality of blocks.

20. The method of claim 19, wherein the program or read operation is performed with respect to a second block selected from among the plurality of blocks while simultaneously erasing the data of the first block.

21. A method of fabricating a non-volatile memory device, comprising:
providing one or more oxide based compound semiconductor layers;
forming a plurality of auxiliary gate electrodes to be insulated from the one or more oxide based compound semiconductor layers;
forming a plurality of control gate electrodes to be respectively positioned between adjacent pairs of the plurality of auxiliary gate electrodes at a different level from the plurality of auxiliary gate electrodes, the plurality of control gate electrodes being insulated from the one or more oxide based compound semiconductor layers; and
forming a plurality of charge storing layers respectively between the one or more oxide based compound semiconductor layers and the plurality of control gate electrodes.

22. The method of claim 21, wherein the providing of the one or more oxide based compound semiconductor layers includes providing a plurality of oxide based compound semiconductor layers separately positioned in strings.

23. The method of claim 21, further comprising:
forming an isolation layer between the plurality of oxide based compound semiconductor layers before forming the plurality of auxiliary gate electrodes.

24. The method of claim 21, wherein the plurality of oxide based compound semiconductor layers are formed on a substrate electrode.

25. The method of claim 21, wherein the plurality of oxide based compound semiconductor layers are formed as a plurality of blocks on a plurality of substrate electrodes.

26. The method of claim 21, wherein the plurality of control gate electrodes are formed on top surfaces of the one or more oxide based compound semiconductor layers, and the plurality of auxiliary gate electrodes are formed to be recessed into the one or more oxide based compound semiconductor layers.

27. The method of claim 21, wherein the plurality of control gate electrodes are formed to be recessed into the one or more oxide based compound semiconductor layers, and the plurality of auxiliary gate electrodes are formed on the top surfaces of the one or more oxide based compound semiconductor layers.

28-34. (canceled)
